(19) United States
(12) Patent Application Publication
(10) Pub. No.: US 2002/0119669 A1
(43) Pub. Date: Aug. 29, 2002

(54) Method of fabricating semiconductor device

(75) Inventors: Yasuhiro Ono, Tokyo (JP); Ken Tokashiki, Tokyo (JP)

Correspondence Address: Patent Group, Hutchins, Wheeler & Dittmar, 101 Federal Street, Boston, MA, 02110, US

(73) Assignee: NEC Corporation

(21) Appl. No.: 10/080,055

(22) Filed: Feb. 21, 2002

(30) Foreign Application Priority Data
Feb. 23, 2001 (JP) 2001-047945

(51) Int. Cl. H01L 21/302; H01L 21/461

(52) U.S. Cl. 438/710

(57) ABSTRACT

A high-dielectric-constant film etching method realizing a high etching rate and, moreover, etching of a highly anisotropic shape is provided. At the time of etching a high-dielectric-constant film, a mask made of an inorganic material is used, a mixed gas of a fluorine gas or fluorine compound gas and an inert gas is used as an etching gas, gaseous oxygen is added to the mixed gas, and the high-dielectric-constant film is etched with the resultant gas.

### BACKGROUND OF THE INVENTION

1. Field of the Invention

The present invention relates to a method of fabricating a semiconductor device and, more particularly, to a method of etching a high-dielectric-constant film suitable for microfabrication of a dielectric material used for a FeRAM, DRAM, or the like.

2. Description of the Related Art

The etching rate of PZT (Pb(Zr,Ti)O₃, PbTiO₃, BaTiO₃, and PLZT ((Pb,La)(Zr,Ti)O₃) with a gas containing chlorine is as low as 100 nm/min or lower, moreover, the taper angle of a PZT processed shape is 70° or less, and it is extremely difficult to perform high anisotropic process for the reasons that reactivity of Pb and Zr as elements of PZT is low and saturated vapor pressure of chlorides and fluorides of Pb and Zr is also extremely low.

### SUMMARY OF THE INVENTION

An object of the present invention is to solve the problems of the conventional technique and to provide a novel semiconductor device fabricating method realizing a high etching rate and etching of a highly anisotropic shape.

To achieve the object, the invention basically employs the technical configuration as described below.

A first aspect of the invention relates to a method of fabricating a semiconductor device, for etching a high-dielectric-constant film by using a mask made of an inorganic material and using, as an etching gas, a mixed gas of a fluorine gas or fluorine compound gas and an inert gas, characterized in that gaseous oxygen is added to the mixed gas, and the high-dielectric-constant film is etched with the resultant gas.

A second aspect is characterized in that an addition amount of the gaseous oxygen is 3 to 10% of the mixed gas.

A third aspect is characterized in that temperature of a semiconductor substrate on which the high-dielectric-constant film is etched lies in a range from 100 to 40020 C.

A fourth aspect is characterized in that the high-dielectric-constant film is a film made of PZT.

A fifth aspect is characterized in that the inorganic mask is a film made of NSG or TiN.

The invention is characterized in that a gas obtained by adding Ar and O₂ to a gas containing a fluorine element is used for dry etching of a dielectric using an inorganic mask and, further, the temperature of a wafer is set to high (100 to 400°C.).

By using a gas containing the fluorine element, the etching rate of the dielectric becomes higher than that in the case of using a chlorine gas. By adding an Ar gas to the gas for dry etching containing the fluorine element, the etching rate of the dielectric becomes higher than that in the case of using the gas containing the fluorine element. Further, by adding oxygen to the gas of the dry etching, the etch selectivity to a mask increases. By setting the temperature of the wafer to a high temperature, the etching rate of the dielectric and the anisotropy of an etched shape are increased.

### BRIEF DESCRIPTION OF THE DRAWINGS

FIGS. 1A to 1F are cross sections showing processes of etching a high-dielectric-constant film of the invention.

FIG. 2 is a graph showing dependency on O₂ added gas flow rate of PZT etching rate and etch selectivity to an NSG mask in a dual-frequency RIE etching system.

FIG. 3 is a graph showing the characteristics of PZT etching rate with respect to an addition ratio of CHF₃ when CHF₃ is added to Ar in a magnetron RIE system.

### DETAILED DESCRIPTION OF THE PREFERRED EMBODIMENT

A concrete example of a method of fabricating a semiconductor device according to the invention will be described in detail hereinafter with reference to the drawings.

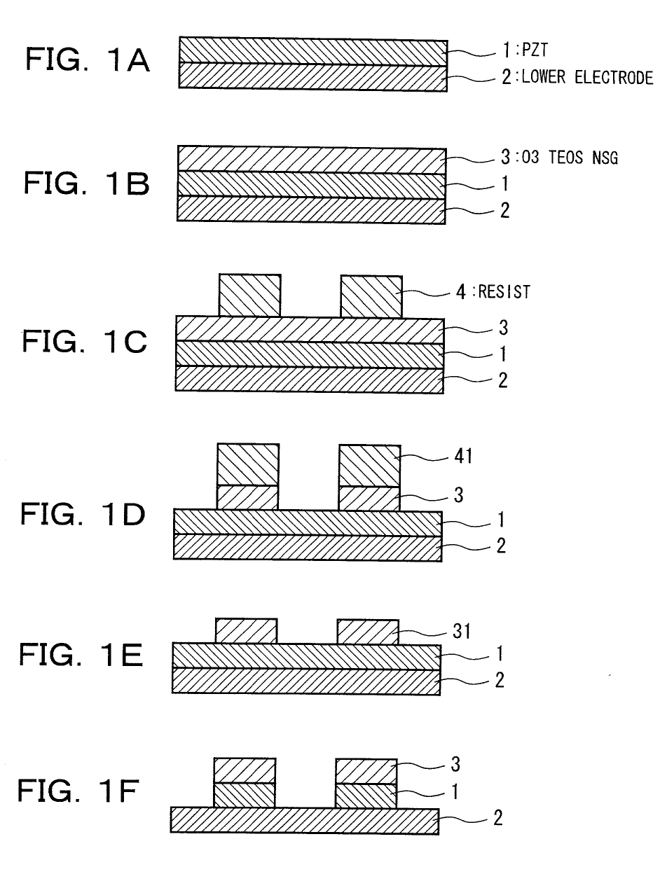

FIGS. 1A to 1F are diagrams showing a first concrete example of a method of etching a high-dielectric-constant film according to the invention. The invention provides a high-dielectric-constant film etching method of etching a high-dielectric-constant film by using a mask made of an inorganic material and using, as an etching gas, a mixed gas of a fluorine gas or fluorine compound and an inert gas, wherein gaseous oxygen is added to the mixed gas, and the high-dielectric-constant film is etched with the resultant.

A concrete example of the invention will be described in more detail hereinafter.

As shown in FIG. 1A, for example, PZT (1) as a dielectric material is deposited to 200 nm on a Pt lower electrode material (2). As shown in FIG. 1B, 03-TEOS NSG (3) as an inorganic mask is formed to have a thickness of 200 nm on the PZT (1). As shown in FIG. 1C, a resist (4) is applied to a thickness of 2.0 μm on the stacked layers and a resist pattern group (41) is formed by photolithography. As shown in FIG. 1D, the 03-TEOS NSG (3) is processed with CF₄ gas by dry etching by using the resist pattern (41) as a mask. After that, as shown in FIG. 1E, the residual resist is remove by ashing using gaseous O₂ and N₂, thereby completing an NSG mask (31). As shown in FIG. 1F, the PZT (1) is etched by dry etching by using the NSG mask (31). By using gases obtained by adding argon and oxygen to a gas containing a fluorine element and setting the wafer temperature to 300° C., the PZT (1) can be etched at a high etching rate (300 nm/min or higher) and, moreover, a highly anisotropic shape (taper angle of 88°) can be formed.

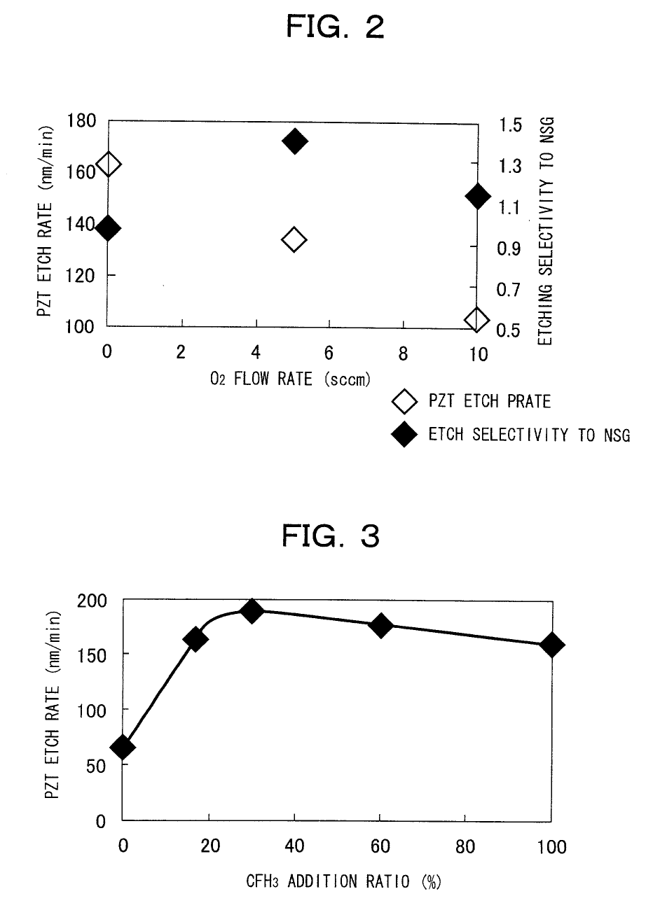

In the present invention, the etching parameters of PZT, particularly, gas composition, and wafer temperature were examined. FIG. 2 shows the dependency on O₂ added gas flow rate of the PZT etching rate and etch selectivity to an NSG mask when a mixed gas obtained by adding O₂ to CF₄ and Ar is used and the wafer temperature is set to 80° C. The flow rates of CF₄ and Ar are fixed to 10 sccm and 40 sccm, respectively. It is understood from FIG. 2 that the maximum etch selectivity to NSG is obtained when the flow rate of O₂ added gas is 5 sccm. The etching selectivity to NSG, when the flow rate of the O₂ added gas is 5 sccm, is 1.4 times as high as that when O₂ is not added. In FIG. 2, the PZT etching rate decreases as the flow rate of the O₂ added gas increases. The PZT etching rate, when the flow rate of the O₂ added gas is 5 sccm, is 0.8 time as high as that when O₂ is not added. It does not conspicuously deteriorate the productivity.

Dependency on gases of the PZT etching rate when the gas total flow rate was 60 sccm and the wafer temperature was 80° C. in the dual-frequency RIE etching system was studied. When the flow rate of Cl₂ was set to 10 sccm and the flow rate of Ar was set to 40 sccm in the mixed gas of Cl₂ and Ar, the PZT etching rate was 49 nm. On the other hand, when the flow rate of CHF₃ was set to 10 sccm and the flow rate of Ar was set to 40 sccm in the mixed gas of CHF₃ and Ar, the PZT etching rate was 123 nm which is more than double of the case of the gases containing Cl₂.

FIG. 3 experimentally shows the characteristics of PZT etching rate with respect to the CHF₃ addition ratio when the total gas flow was 28 sccm, the wafer temperature was set to 60° C., and CHF₃ was added to Ar in a magnetron RIE system. It is understood from FIG. 3,that the PZT etching rate becomes the maximum value when the CHF₃ addition ratio is 30%. The PZT etching rate when the CHF₃ addition ratio is 30% is 1.2 times as high as that when the CHF₃ addition ratio is 100%.

The dependency on the wafer temperature of the PZT etching rate and etch selectivity to the NSG mask when a mixed gas obtained by adding O₂ to CF₄ and Ar in an inductively coupled plasma etching system was studied. The flow rates of CF₄, Ar, and O₂ were 15 sccm, 35 sccm, and 30 sccm, respectively. The PZT etching rate and the etch selectivity to the NSG mask when the wafer temperature was 80° C. were 132 nm/min and 1.38, respectively. The PZT etching rate and the etching selectivity to the NSG mask when the wafer temperature was 300° C. were 317 nm/min and 4.45, respectively. When the wafer is set to a higher temperature, the PZT etching rate and the etching selectivity to the NSG mask increase. When the wafer temperature is 100° C. or lower, the etching rate and the etch selectivity are low. When the wafer temperature exceeds 400° C., it is feared that the quality of a PZT film changes. Consequently, the wafer temperature in a range from 100 to 400° C. is appropriate.

Although the NSG (Non-doping Silicate Glass) was used as an inorganic mask material in the concrete examples, TiN may be also used as the inorganic mask material.

Although the elements of PZT are Pb, Zr, Ti, and O, the PZT may contain, for example, elements of La, Sr, and Ca.

According to the invention, with the configuration as described above, high etching rate and etching of a highly anisotropic shape are achieved.

What is claimed is:

1. A method of fabricating a semiconductor device, for etching a high-dielectric-constant film by using a mask made of an inorganic material and using, as an etching gas, a mixed gas of a fluorine gas or fluorine compound gas and an inert gas,
wherein gaseous oxygen is added to said mixed gas, and said high-dielectric-constant film is etched with the resultant gas.

2. The method of fabricating a semiconductor device according to claim 1, wherein an addition amount of said gaseous oxygen is 3 to 10% of said mixed gas.

3. The method of fabricating a semiconductor device according to claim 1, wherein temperature of a semiconductor wafer on which said high-dielectric-constant film is etched lies in a range from 100 to 400° C.

4. The method of fabricating a semiconductor device according to claim 1, wherein said high-dielectric-constant film is a film made of PZT.

5. The method of fabricating a semiconductor device according to claim 1, wherein said inorganic mask is a film made of NSG or TiN.
